(19) United States
(12) Patent Application Publication
(10) Pub. No.: US 2025/0210474 A1
(43) Pub. Date: Jun. 26, 2025

(54) SEMICONDUCTOR APPARATUS

(71) Applicants: KABUSHIKI KAISHA TOSHIBA, Tokyo (JP); Toshiba Electronic Devices & Storage Corporation, Tokyo (JP)

(72) Inventors: Yoshiki Endo, Kawasaki Kanagawa (JP); Toshihide Takahashi, Yokohama Kanagawa (JP)

(73) Assignees: KABUSHIKI KAISHA TOSHIBA, Tokyo (JP); Toshiba Electronic Devices & Storage Corporation, Tokyo (JP)

(21) Appl. No.: 19/077,148

(22) Filed: Mar. 12, 2025

Related U.S. Application Data
(63) Continuation of application No. PCT/JP2024/008125, filed on Mar. 4, 2024.

(30) Foreign Application Priority Data
Jul. 18, 2023 (JP) 2023-116956

(51) Int. Cl. H01L 23/495; H01L 23/00

(52) U.S. Cl. CPC H01L 23/49548; H01L 23/49513; H01L 23/49575; H01L 24/32; H01L 24/83; H01L 24/33; H01L 2224/32059; H01L 2224/32258; H01L 2224/33181; H01L 2224/83815

(57) ABSTRACT

According to one embodiment, A semiconductor apparatus includes: a pellet including a first surface on which a plurality of pads are provided; a first bonding material provided on the first surface; and a first metal plate provided on the first bonding material, electrically connected to the plurality of pads, and including a second surface facing the first surface and a plurality of protrusions provided on the second surface, wherein the plurality of protrusions respectively face one pad of the plurality of pads disposed at an end and another pad of the plurality of pads disposed at the other end in a direction in which the plurality of pads are aligned.

### CROSS-REFERENCE TO RELATED APPLICATIONS

This application is a Continuation Application of PCT Application No. PCT/JP2024/008125, filed Mar. 4, 2024 and based upon and claiming the benefit of priority from Japanese Patent Application No. 2023-116956, filed Jul. 18, 2023, the entire contents of all of which are incorporated herein by reference.

### FIELD

An embodiment of the present invention relates generally to a semiconductor apparatus.

### BACKGROUND

A semiconductor apparatus having a structure in which an upper surface and a lower surface of a pellet are connected to conductors via bonding materials is known.

### BRIEF DESCRIPTION OF THE DRAWINGS

FIG. 1 is a bird's-eye view illustrating an example of an external appearance of a semiconductor apparatus according to an embodiment.

FIG. 2 is an exploded view illustrating an example of an internal structure of the semiconductor apparatus according to the embodiment.

FIG. 3 is a plan view illustrating an example of a planar layout of the semiconductor apparatus according to the embodiment.

FIG. 4 is a cross-sectional view illustrating an example of a cross-sectional structure of the semiconductor apparatus according to the embodiment.

FIG. 5 is a cross-sectional view illustrating an example of an element structure of the semiconductor apparatus according to the embodiment.

FIG. 6 is a plan view illustrating an example of a structure of a metal plate of the semiconductor apparatus according to the embodiment.

FIG. 7 is a cross-sectional view illustrating an example of a structure of the metal plate of the semiconductor apparatus according to the embodiment.

FIG. 8 is a cross-sectional process view illustrating a step of a method for manufacturing the semiconductor apparatus according to the embodiment.

### DETAILED DESCRIPTION

In general, according to one embodiment, a semiconductor apparatus includes: a pellet including a first surface on which a plurality of pads are provided; a first bonding material provided on the first surface; and a first metal plate provided on the first bonding material, electrically connected to the plurality of pads, and including a second surface facing the first surface and a plurality of protrusions provided on the second surface, wherein the plurality of protrusions respectively face one pad of the plurality of pads disposed at an end and another pad of the plurality of pads disposed at the other end in a direction in which the plurality of pads are aligned.

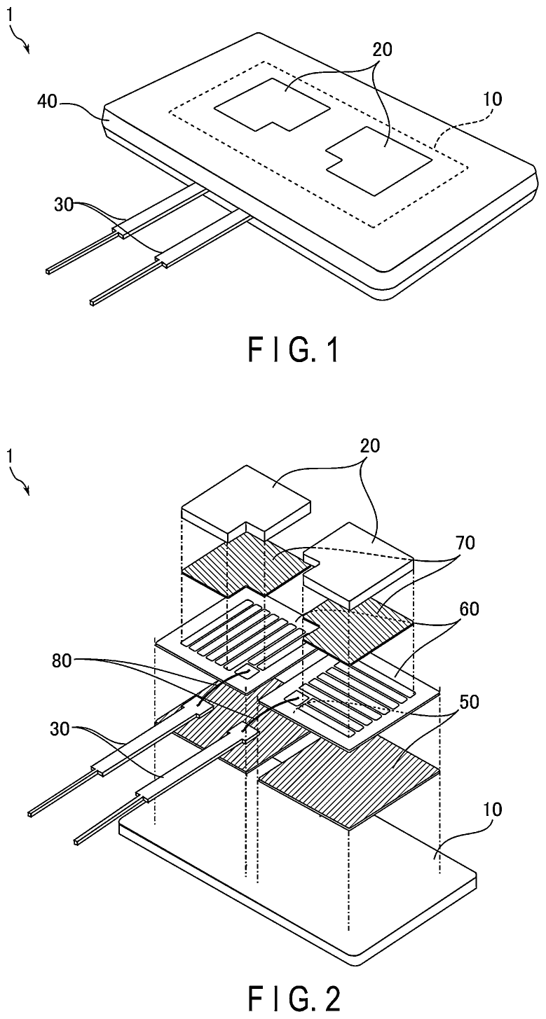

A semiconductor apparatus according to an embodiment will be described with reference to FIGS. 1 to 8. In the following description, components having substantially the same function and configuration are denoted by the same reference numerals. In a case where the components having similar configurations are particularly distinguished from each other, different characters or numbers may be added to the end of the same reference numeral. Dimensions and ratios of the drawings are not necessarily the same as actual ones.

### Embodiment

### (a) Structural Example

A structural example of the semiconductor apparatus according to the embodiment will be described with reference to FIGS. 1 to 7.

FIG. 1 is a bird's-eye view illustrating an example of an external appearance of the semiconductor apparatus according to the embodiment.

The semiconductor apparatus 1 according to the embodiment in FIG. 1 is a power device. The semiconductor apparatus 1 has, for example, a thin rectangular parallelepiped shape. Hereinafter, the thickness direction of the semiconductor apparatus 1 is referred to as a vertical direction. Furthermore, in a case where the components of the semiconductor apparatus 1 have two surfaces that face downward and upward, the two surfaces are referred to as a lower surface and an upper surface, respectively.

The semiconductor apparatus 1 includes a metal plate 10, two metal plates 20, two lead portions 30, and a sealing material 40. Each of the metal plate 10, the two metal plates 20, and the two lead portions 30 has a portion exposed to the outside of the sealing material 40 as a terminal for electrical connection between the semiconductor apparatus 1 and another device.

Each of the metal plate 10 and the two metal plates 20 is provided so as to be exposed to the lower surface and the upper surface of the sealing material 40. For example, the height of the exposed surface of the metal plate 10 is aligned with the height of the lower surface of the sealing material 40. For example, the height of the exposed surfaces of each metal plates 20 is aligned with the height of the upper surface of the sealing material 40. In a case where viewed from a direction perpendicular to the upper surface (and the lower surface) of the semiconductor apparatus 1, the exposed surface of each of the metal plate 20 is included in an area of the exposed surface of the metal plate 10.

Hereinafter, the metal plate 10 on the lower surface side of the semiconductor apparatus 1 is referred to as a lower metal plate 10, and each of the metal plates 20 on the upper surface side of the semiconductor apparatus 1 is referred to as an upper metal plate 20.

The two lead portions 30 are provided so as to be exposed to the side surface of the sealing material 40. For example, the two lead portions 30 protrude from the side surface of the sealing material 40.

The sealing material 40 is an insulating member that physically and electrically protects an internal structure of the semiconductor apparatus 1 from the outside. The sealing material 40 forms the outer shape of the semiconductor apparatus 1.

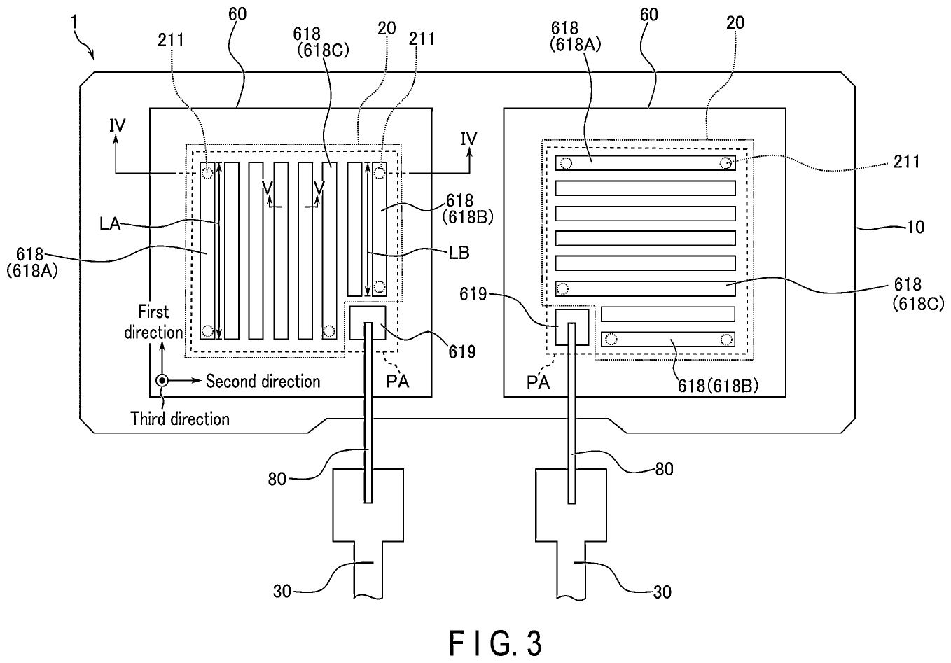

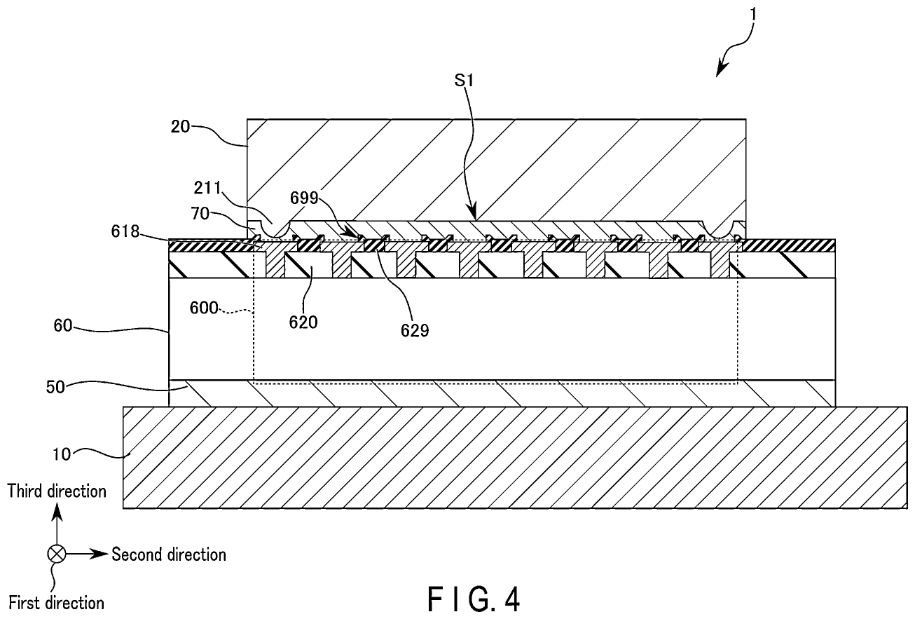

FIGS. 2 to 4 are diagrams for explaining the internal structure of the semiconductor apparatus 1 according to the present embodiment. FIG. 2 is an exploded view illustrating an example of the internal structure of the semiconductor apparatus 1 according to the embodiment. FIG. 2 schematically illustrates the internal structure of the semiconductor apparatus 1 disassembled in the thickness direction. FIG. 3 is a plan view illustrating an example of a planar layout inside the semiconductor apparatus 1 according to the embodiment. FIG. 4 is a cross-sectional view taken along the line IV-IV in FIG. 3, illustrating an example of the internal cross-sectional structure of the semiconductor apparatus 1 according to the embodiment. In FIGS. 2, 3, and 4, illustration of the sealing material 40 is omitted.

As illustrated in FIGS. 2 to 4, the semiconductor apparatus 1 further includes, as the internal structure, two bonding materials 50, two pellets 60, two bonding materials 70, and two wires 80, in addition to the lower metal plate 10, the two upper metal plates 20, and the two lead portions 30.

The lower metal plate 10 is a plate-shaped conductor. One surface of the lower metal plate 10 faces surfaces in one side (lower surfaces) of the pellets 60. The surface of the lower metal plate 10 facing the pellets 60 is referred to as an upper surface of the lower metal plate 10. In the lower metal plate 10, the other surface parallel to the upper surface of the lower metal plate 10 is referred to as a lower surface of the lower metal plate 10. The lower surface of the lower metal plate 10 corresponds to the surface of the lower metal plate 10 exposed from the sealing material 40. Each of the upper surface and the lower surface of the lower metal plate 10 is flat over the entire surface. Protrusions that protrude toward the pellets 60 may be provided on the upper surface of the lower metal plate 10. In this case, recesses may be provided at positions on the lower surface of the lower metal plate 10 corresponding to the protrusions provided on the upper surface of the lower metal plate 10.

The upper metal plate 20 is a plate-shaped conductor. The upper metal plate 20 has a surface S1 facing a surface on the other side (upper surface) of the pellet 60. The surface S1 of the upper metal plate 20 facing the pellet 60 is referred to as a lower surface S1 of the upper metal plate 20. In the upper metal plate 20, the other surface parallel to the lower surface S1 of the upper metal plate 20 is referred to as an upper surface of the upper metal plate 20. The upper surface of the upper metal plate 20 corresponds to the surface of the upper metal plate 20 exposed from the sealing material 40. In the present embodiment, the upper metal plate 20 includes a plurality of protrusions 211 provided on the lower surface S1 side of the upper metal plate 20. The upper surface of the upper metal plate 20 may be flat over the entire surface, for example. Alternatively, recesses may be provided at a part of the upper surface of the upper metal plate 20, for example, at positions of the upper surface corresponding to the protrusions 211 provided on the lower surface S1. Details of the structure of the upper metal plate 20 will be described later.

Each of the lower metal plate 10 and the upper metal plates 20 is, for example, a copper plate. The copper plate of the lower metal plate 10 and the copper plates of the upper metal plates 20 have a thickness of about 1.5 mm.

The two bonding materials 50 are provided apart from each other on the upper surface of the lower metal plate 10. The corresponding pellets 60 are provided on the upper surfaces of the bonding materials 50. Each bonding material 50 is provided between the lower metal plate 10 and the corresponding pellet 60. The bonding material 50 bonds the lower metal plate 10 and the pellet 60 together. The bonding material 50 contacts the flat lower surface of the pellet 60. The bonding material 50 is a conductor. The bonding material 50 is, for example, a plate-like solder layer (for example, a solder sheet).

The pellet (a semiconductor chip, a semiconductor substrate, and a semiconductor element) 60 is provided between the lower metal plate 10 and the upper metal plate 20. For example, the area of the lower surface of the pellet 60 is smaller than the area of the upper surface of the lower metal plate 10. For example, the area of the upper surface of the pellet 60 is larger than the area of the lower surface of the upper metal plate 20.

The pellet 60 is a chip including a semiconductor element such as a power semiconductor device. The power semiconductor device of the pellet 60 is, for example, a device using silicon (Si) or silicon carbide (SiC). As an example of the power semiconductor device, in a case where silicon is used in the pellet 60, the pellet 60 is an insulated gate bipolar transistor (IGBT). As another example of the power semiconductor device, in a case where silicon carbide is used in the pellet 60, the pellet 60 is a metal-oxide-silicon field effect transistor (MOSFET). The pellet 60 includes an element unit 600. The element unit 600 includes a plurality of constituent members of the semiconductor element. In addition, a termination structure (not illustrated) is provided in a region between the end portion of the pellet 60 and the element unit 600 in a direction parallel to the upper surface of the pellet 60.

A plurality of pads 618 and 619 are provided on the upper surface (the surface of the upper metal plate 20) side of the pellet 60. Each of the pads 618 and 619 is electrically connected to a constituent member on the semiconductor substrate included in the element unit 600 and/or a constituent member in the semiconductor substrate.

An insulating layer 629 is provided between the adjacent pads 618. The insulating layer 629 is, for example, a polyimide layer. For example, the upper surfaces of the pads 618 and 619 are exposed through openings provided in the insulating layer 629. The position of the upper surface of the insulating layer 629 in the third direction is higher than the positions of the upper surfaces of the pads 618 and 619 in the third direction. Therefore, steps 699 are generated between the upper surfaces of the pads 618 and 619 and the upper surface of the insulating layer 629.

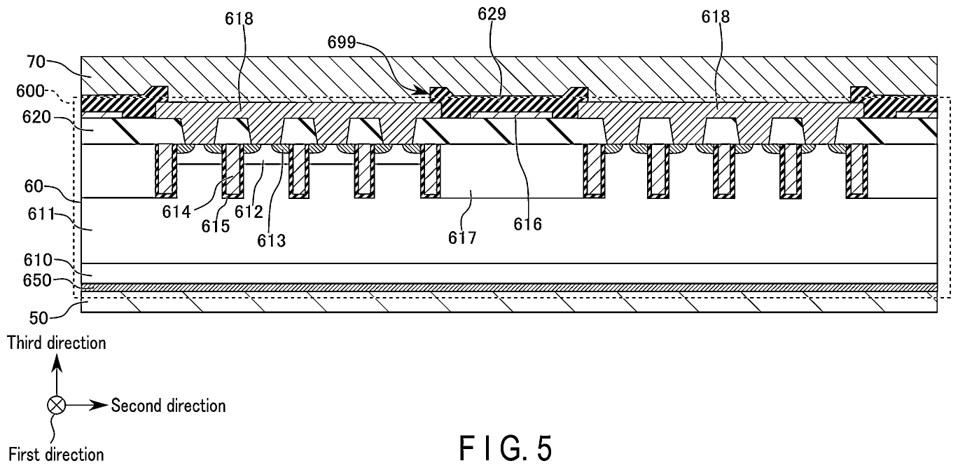

FIG. 5 is a cross-sectional view illustrating an example of an element structure of an IGBT as the semiconductor apparatus 1 according to the present embodiment. FIG. 5 illustrates a cross section taken along the line V-V in FIG. 3.

As illustrated in FIG. 5, in a case where the semiconductor element formed in the pellet 60 is an IGBT, a semiconductor layer 610, a semiconductor layer 611, a plurality of semiconductor layers 612, a plurality of semiconductor layers 613, a plurality of gate electrodes 614, a plurality of gate insulating layers 615, a gate interconnect 616, a semiconductor layer 617, the plurality of pads (conductive patterns) 618 and 619, an electrode 650, and an insulating layer 620 are provided in the pellet 60 as constituent members of the element unit 600. A termination structure (not illustrated) is provided at an end of the pellet 60 in a direction parallel to the upper surface of the pellet 60.

The semiconductor layer 610 is provided on the lower surface side of the pellet 60. The semiconductor layer 610 is a diffusion layer (impurity semiconductor region) formed in the semiconductor substrate of the pellet 60. The semiconductor layer 610 is electrically connected to the lower metal plate 10 via the bonding material (solder layer) 50. The lower surface of the semiconductor layer 610 is substantially flat. The semiconductor layer 610 is a semiconductor layer as a collector of the IGBT.

For example, the electrode 650 is provided between the semiconductor layer 610 and the solder layer 50. The electrode 650 improves solder wettability and bondability between the solder layer 50 and the pellet 60. The electrode 650 functions as a barrier film for suppressing penetration (diffusion) of the solder material into the pellet 60. For example, the electrode 650 is a stacked film including a titanium film (Ti film), a nickel film (Ni film), and a silver film (Ag film).

The semiconductor layer 611 is provided in a semiconductor region defined by an element isolation layer (not illustrated) in the semiconductor substrate. The semiconductor layer 611 is, for example, a semiconductor layer as a drift layer of the IGBT.

The plurality of semiconductor layers 612 are provided in the semiconductor layer 611. Each of the semiconductor layers 612 is a semiconductor layer as a base of the IGBT.

Each of the plurality of semiconductor layers 613 is provided in the semiconductor layer 612. Each semiconductor layer 613 is a semiconductor layer as an emitter of the IGBT.

The gate electrodes 614 are trench gates. The gate electrodes 614 are provided in the pellet 60 via the gate insulating layers 615. The gate insulating layers 615 are provided between the gate electrodes 614 and the semiconductor layers 611, 612, and 613. The gate electrodes 614 are sandwiched between the two semiconductor layers 612 and between the two semiconductor layers 613. The side surfaces of the gate electrodes 614 face the semiconductor layers 612 and the semiconductor layers 613 via the gate insulating layers 615. The gate electrode 614 is a conductive layer as the gate electrode 614 of the IGBT.

The gate interconnect 616 is disposed in a region between the two pads 618 adjacent in the second direction. The gate interconnect 616 is provided on the insulating layer 620. The semiconductor layer 617 is provided in the semiconductor region below the gate interconnect 616 via the insulating layer 620.

Conductivity types of the semiconductor layers 610, 611, 612, 613, and 617 are set to an N type or a P type according to a drive type of the IGBT. A semiconductor layer other than the semiconductor layers 610, 611, 612, 613, and 617 may be provided in the pellet 60 according to the function and characteristics required for the IGBT.

The pads 618 and 619 are provided on the upper surface side of the pellet 60. The pads 618 and 619 are conductors.

The plurality of pads 618 are provided on the insulating layer 620 covering the upper surface of the semiconductor substrate of the pellet 60. Each pad 618 is in contact with the semiconductor layers 612 and 613 via an opening (contact hole) in the insulating layer 620. The pad 618 is electrically connected to the semiconductor layers 612 and 613. The pad 618 is a pad for electrically connecting the emitter of the IGBT and the upper metal plate 20. Each pad 618 has, for example, a rectangular pattern. The pad 618 extends in a first direction parallel to the upper surface of the pellet 60 when viewed from the upper surface of the pellet 60. The plurality of pads 618 are arranged in a second direction intersecting the first direction and parallel to the upper surface of the pellet 60. Hereinafter, the pad 618 is also referred to as an emitter pad 618.

The pads 618 and 619 are stacked films including an aluminum film (Al film), a nickel film (Ni film), and a gold film (Au film). The gold film prevents oxidation of the nickel film on the aluminum film of the pads 618 and 619. The bonding property between the bonding material (for example, a solder layer) 70 and the pellet 60 is secured by the nickel film.

The insulating layer 629 is provided on the gate interconnect 616. The insulating layer 629 overlaps the ends of the pads 618. The steps 699 are provided between the insulating layer 629 and the pads 618.

Returning to FIGS. 3 and 4, for example, the plurality of emitter pads 618 includes emitter pads 618A, 618B, and 618C. The emitter pad 618A is disposed closest to one end side in the alignment direction (the second direction) of the plurality of emitter pads 618. The emitter pad 618B is disposed closest to the other end side in the alignment direction of the plurality of emitter pads 618. The emitter pad 618B is adjacent to the pad 619 in the extending direction (the first direction) of the emitter pad 618. A dimension (length) LB of the emitter pad 618B in the extending direction is smaller than a dimension LA of the emitter pad 618A in the extending direction. The emitter pad 618C is disposed in a region between the emitter pad 618A and the emitter pad 618B. A certain portion of the emitter pad 618C is adjacent to the pad 619 in the alignment direction of the emitter pads 618. The dimension in the extending direction of the emitter pad 618C is the same as the dimension LA in the extending direction of the emitter pad 618A.

The step 699 is generated between the upper portion of the emitter pad 618 and the upper portion of the insulating layer 620. Due to the steps 699, a groove is formed above the emitter pad 618.

One pad 619 is provided on the insulating layer 620. The pad 619 is electrically connected to the gate electrode 614 via a gate interconnect (not illustrated) in the pellet 60 and a contact plug (not illustrated) in the insulating layer 620. For example, the pad 619 is disposed in a certain corner region in the area PA where the pads 618 and 619 are provided. The pad 619 has, for example, a square pattern. Hereinafter, the pad 619 connected to the gate electrode 614 is referred to as a gate pad 619.

Hereinafter, a region where the plurality of emitter pads 618 and the gate pad 619 are arranged on the upper surface of the pellet 60 is referred to as a pad arrangement area PA.

In a case where the pellet 60 is an IGBT, the lower metal plate 10 is a collector electrode (collector terminal), and the upper metal plate 20 is an emitter electrode (emitter terminal). In a case where the pellet 60 is a MOSFET, for example, the lower metal plate 10 is a drain electrode, and the upper metal plate 20 is a source electrode.

The two bonding materials 70 are disposed separated from each other. Each of the two bonding materials 70 is provided on a region including the emitter pad 618 and excluding the gate pad 619 on the upper surface (pad arrangement area PA) of the pellet 60. The corresponding upper metal plate 20 is provided on the upper surface of the bonding material 70. Each bonding material 70 is provided between the corresponding upper metal plate 20 and the corresponding pellet 60. The bonding material 70 bonds the upper metal plate 20 and the pellet 60 together. The bonding material 70 contacts the undulating upper surface of the pellet 60. The bonding material 70 is a conductor. The bonding material 70 is, for example, a plate-like solder layer (solder sheet).

The bonding material 70 is provided on the upper surface of the pellet 60 so as to cover the emitter pads 618. The bonding material 70 is in contact with the emitter pads 618. As a result, the upper metal plate 20 is electrically connected to the plurality of emitter pads 618 via the bonding material 70. The bonding material 70 does not contact the gate pad 619. For example, the bonding material 70 does not extend in the region between the end of the pad arrangement area PA and the end of the pellet 60.

One end of the corresponding wire 80 is provided on the gate pad 619 on the upper surface of the pellet 60. The wire 80 is a bonding wire. The other end of the wire 80 is connected to the corresponding lead portion 30. The lead portion 30 is a gate electrode (gate terminal).

With the above configuration, in the semiconductor apparatus 1, three terminals used for input and output of the pellet 60 are electrically connected to the collector electrode 10, the emitter electrode 20, and the gate electrode 30. The bonding material 50 and the bonding material 70 electrically connect the pellet 60 and the metal plates (electrodes) 10 and 20, and have a function of dissipating, in the vertical direction, heat generated in the pellet 60.

Note that, in FIGS. 1 to 5, a case where the two pellets 60 are provided in the semiconductor apparatus 1 has been described, but the present invention is not limited thereto. The number of pellets 60 provided in the semiconductor apparatus 1 may be one or three or more.

In the semiconductor apparatus 1 according to the present embodiment, the upper metal plate 20 includes a plurality of protrusions 211 provided on the lower surface S1 of the upper metal plate 20.

As a result, the semiconductor apparatus 1 according to the present embodiment can prevent bonding failure and electrical connection failure between the upper metal plate 20 and the pellet 60.

### Upper Metal Plate

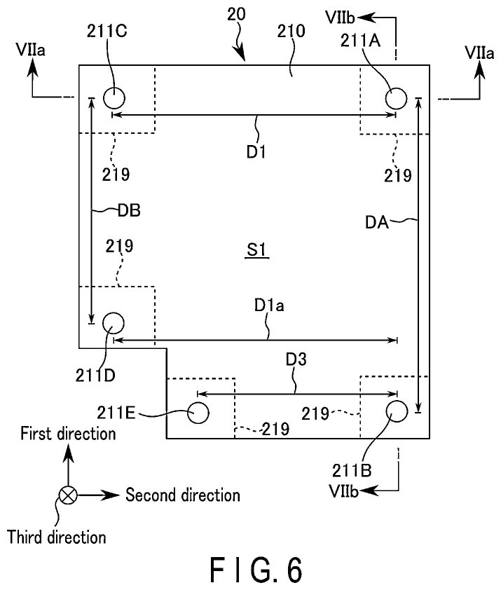

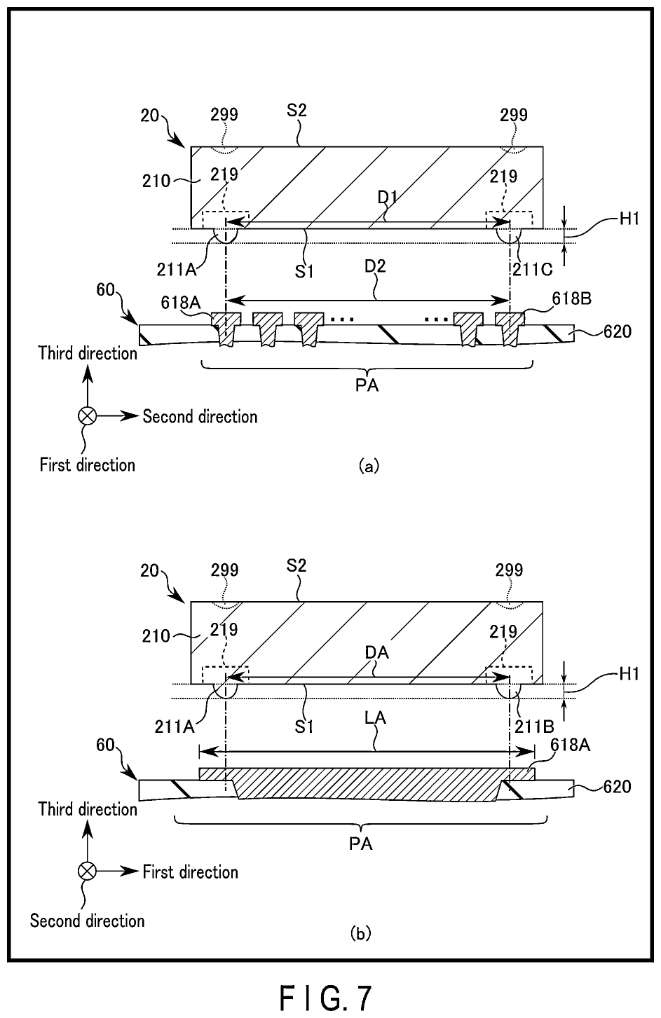

FIGS. 6 and 7 are diagrams for explaining a structural example of the upper metal plate 20 of the semiconductor apparatus 1 according to the present embodiment. FIG. 6 is a plan view illustrating the structural example of the upper metal plate 20 in the semiconductor apparatus 1 according to the present embodiment. FIG. 7 is a cross-sectional view illustrating the structural example of the upper metal plate 20 in the semiconductor apparatus 1 according to the present embodiment. (a) of FIG. 7 is a cross-sectional view taken along the line VIIa-VIIa in FIG. 6. (b) of FIG. 7 is a cross-sectional view taken along the line VIIb-VIIb in FIG. 6. FIG. 7 schematically illustrates a part of the structure of the pellet 60 in order to illustrate the positional relationship between the protrusions 211 of the upper metal plate 20 and the pads 618 of the pellet 60.

As described above, in a case where the semiconductor apparatus 1 is an IGBT, the upper metal plate 20 is an emitter electrode.

As illustrated in FIGS. 6 and 7, the upper metal plate 20 includes a plate portion 210 and the plurality of protrusions 211.

The plate portion 210 is a plate-shaped conductor. The plate portion 210 has the two surfaces S1 and S2. The two surfaces S1 and S2 are parallel to each other. The surface S1 is a surface of the upper metal plate 20 facing the pellet 60. The surface S2 is a surface exposed from the sealing material 40. The surface S1 is referred to as a lower surface, and the surface S2 is referred to as an upper surface.

The lower surface S1 of the upper metal plate 20 has the plurality of protrusions 211 (211A, 211B, 211C, 211D, and 211E). On the lower surface S1 of the upper metal plate 20, for example, four or more protrusions 211 are provided on the plate portion 210. On the lower surface S1 of the upper metal plate 20, a portion of the plate portion 210 other than the protrusion 211 is flat.

The upper surface S2 of the upper metal plate 20 (plate portion 210) is, for example, flat. However, as described above, recesses 299 may be provided at positions corresponding to the protrusions 211 on the upper surface S2 of the upper metal plate 20.

The protrusions 211 are provided in regions 219 near corners of the plate portion 210 when viewed from a direction perpendicular to the lower surface S1. Hereinafter, the regions 219 are referred to as corner regions.

The protrusion 211 has, for example, a hemispherical or semi-ellipsoidal shape. The protrusion 211 may have a cubic shape, a rectangular parallelepiped shape, a triangular pyramid shape, or a quadrangular pyramid shape.

The plurality of protrusions 211 have the same height (dimension in a direction perpendicular to the lower surface S1). For example, each protrusion 211 has a height H1. The height H1 of the protrusion 211 is a dimension from the flat portion of the surface S1 of the plate portion 210 on the side where the protrusion 211 is provided to the top portion of the protrusion 211 (the position most protruding from the surface S1) in a direction perpendicular to the lower surface S1.

The plurality of protrusions 211 are arranged in the lower surface S1 of the upper metal plate 20 so as to vertically overlap the positions of the corners of the area where the plurality of emitter pads 618 are arranged. The protrusions 211 are provided at positions facing the emitter pads 618 on the outer peripheral side of the pellet 60 when viewed from a direction perpendicular to the lower surface S1. The protrusions 211 vertically overlap the ends of the emitter pads 618 in the extending direction of the pattern of the emitter pads 618 in the direction perpendicular to the lower surface S1.

For example, five protrusions 211A, 211B, 211C, 211D, and 211E are provided on the upper metal plate 20.

Of the five protrusions 211, two protrusions 211 (211A and 211B) are provided at positions vertically overlapping the emitter pad 618A on at an end in one side in the direction in which the emitter pads 618 are aligned (the second direction), among the plurality of emitter pads 618.

The other two protrusions 211 (211C and 211D) are provided at positions vertically overlapping the emitter pad 618B at an end in the other side in the direction in which the emitter pads 618 are aligned, among the plurality of emitter pads 618. The emitter pad 618B on the other end side is adjacent to the gate pad 619 in the extending direction of the emitter pads 618 (the first direction).

One (protrusion 211A or 211C) of the two protrusions 211 overlapping a certain emitter pad 618 (618A or 618B) vertically overlaps one end of the emitter pad 618 in the extending direction of the emitter pad 618. The other (protrusion 211B or 211D) of the two protrusions 211 overlapping the certain emitter pad 618 (618A or 618B) vertically overlaps the other end of the emitter pad 618 in the extending direction of the emitter pad 618.

A distance between two protrusions 211 facing a certain emitter pad 618 is smaller than a dimension (length) in the extending direction of the emitter pad 618. For example, an interval DA between the two protrusions 211A and 211B in the first direction is smaller than a length LA of the emitter pad 618A in the first direction. The interval DA is a dimension between the top of the protrusion 211A and the top of the protrusion 211B. For example, an interval DB between the two protrusions 211C and 211D in the first direction is smaller than a length LB of the emitter pad 618B in the first direction. The interval DB is a dimension between the top of the protrusion 211C and the top of the protrusion 211D.

The interval between the two protrusions 211 overlapping the different emitter pads 618 is substantially equal to the interval between the two emitter pads 618A and 618B provided at one end and the other end of the outer periphery of the pad arrangement area PA. For example, an interval D1 between the protrusion 211A and the protrusion 211C in the second direction is substantially equal to an interval D2 between the emitter pad 618A on the one end side and the emitter pad 618B on the other end side in the second direction. For example, the interval D1 is a dimension between the top of the protrusion 211A and the top of the protrusion 211D. For example, the interval D2 is a dimension between a center line along the first direction of the emitter pad 618A on the one end side and a center line along the first direction of the emitter pad 618B on the other end side.

For example, an interval Dla between the protrusion 211B and the protrusion 211D in the second direction is substantially equal to the interval D1 between the protrusion 211A and the protrusion 211C in the second direction. For example, an interval D3 between the protrusion 211B and the protrusion 211E in the second direction is smaller than the interval D1 between the protrusion 211A and the protrusion 211C in the second direction.

The protrusion 211E of the five protrusions 211 is provided at a position vertically overlapping one end of the emitter pad 618C adjacent to the gate pad 619 in the alignment direction of the pads 618. The protrusion 211E is adjacent to a certain corner of the gate pad 619. For example, the protrusion 211 is not provided at a position vertically overlapping the other end of the emitter pad 618C. Therefore, the other end of the emitter pad 618C does not vertically overlap the protrusion 211. However, a protrusion 211 may be provided on the lower surface S1 of the upper metal plate 20 at a position vertically overlapping the other end of the emitter pad 618C. Note that the protrusion 211E may not be provided.

Another protrusion 211 may be provided on the metal plate 20 at a position facing a portion other than the end portion of the emitter pad 618C as long as it is within the region where the corner is formed in the upper metal plate 20. A portion other than the end portion of the emitter pad 618C (a portion including a position facing another protrusion 211) is arranged at another corner portion on a side of the gate pad 619 adjacent to the emitter pad 618C.

A space is formed between the plate portion 210 and the upper surface of the pellet 60 by the protrusions 211 having the height H1.

As described above, the solder layer 70 is provided between the upper metal plate 20 and the pellet 60. For example, the solder layer 70 is interposed between the protrusions 211 and the emitter pads 618, between the plate portion 210 and the emitter pads 618, and between the plate portion 210 and the insulating layer 620. The corner portions of the solder layer 70 vertically overlap the protrusions 211 of the upper metal plate 20 in a direction perpendicular to the upper surface of the solder layer 70 (the upper surface of the pellet 60 or the lower surface S1 of the upper metal plate 20). The protrusions 211 may be in direct contact with the emitter pads 618 without interposition of the solder layer 70.

The protrusions 211 function as a base point of melting of the solder during melting of the solder in the manufacturing process of the semiconductor apparatus 1. The protrusions 211 can suppress the turn-up and/or sink marks of the solder layer (solder sheet) during the manufacturing process of the semiconductor apparatus 1.

### (b) Manufacturing Method

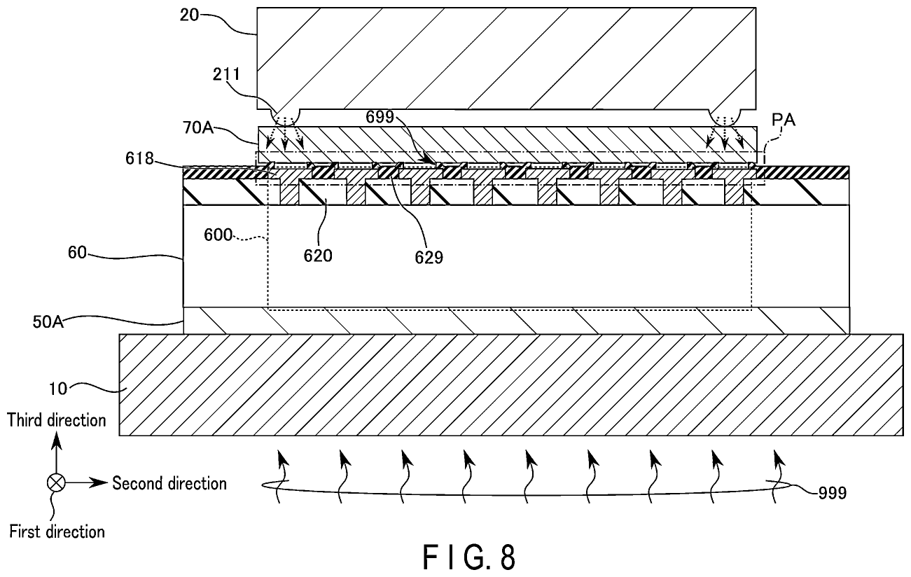

A method for manufacturing the semiconductor apparatus 1 according to the present embodiment will be described with reference to FIG. 8. FIG. 8 is a cross-sectional process view illustrating a step of the method for manufacturing the semiconductor apparatus 1 according to the present embodiment.

As illustrated in FIG. 8, in the manufacturing process of the semiconductor apparatus 1 according to the present embodiment, the pellet 60 including the power device is stacked on the lower metal plate 10 via a solder sheet 50A. The solder sheet 50A is in contact with the flat lower surface of the pellet 60. The solder sheet 50A is a member for forming a solder layer (bonding material) between the lower metal plate 10 and the pellet 60.

At the top surface of the pellet 60, the steps 699 are formed between the patterns of the emitter pads 618. The insulating layer (for example, a polyimide layer) 629 protrudes at the portions of the steps 699. On the upper surface of the pellet 60, the portions of the pads 618 made of metal and the portions of the insulating layer 629 are alternately arranged. The groove is formed in a space surrounded by the insulating layer 629 above the emitter pad 618.

A solder sheet 70A is stacked on the upper surface of the pellet 60. The solder sheet 70A is in contact with the undulating upper surface of the pellet 60. The solder sheet 70A is a member for forming a solder layer (bonding material) between the upper metal plate 20 and the pellet 60.

The upper metal plate 20 is stacked on the pellet 60 via the solder sheet 70A. The protrusions 211 of the upper metal plate 20 is disposed above the pads 618 on the outer peripheral side of the pellet 60 in a direction perpendicular to the upper surface of the pellet 60 via the solder sheet 70A.

After stacking the upper metal plate 20, heat (or ultrasonic waves) 999 is supplied to the stack including the pellets 60 sandwiched between the metal plates 10 and 20 for melting the solder sheets 50A and 70A. By supplying heat, the solder sheets 50A and 70A are melted. For example, the heat 999 is supplied to the pellet 60 from the lower metal plate 10 side.

In an initial stage of heat supply in the soldering process (solder reflow process), the supplied heat is propagated from the protrusions 211 of the upper metal plate 20 to the solder sheet 50A. At this time, the solder sheet 70A on the upper surface of the pellet 60 melts with the plurality of protrusions 211 provided on the upper metal plate 20 as base points. As described above, according to the present embodiment, the melting of the solder sheet 70A starts from the outer peripheral side in the pad arrangement area PA. Further, the end of the solder sheet 70A is pressed against the emitter pads 618 on the outer periphery of the pad arrangement area PA by the protrusions 211 of the upper metal plate 20.

Therefore, in the present embodiment, the solder turn-up and/or sink marks on the outer peripheral side of the pad arrangement area PA are suppressed. Therefore, the molten solder wets and spreads over the entire upper surface of the pellet 60 without adverse effects of the steps 699 between the pads 618. The pellet 60 having the plurality of emitter pads on the upper surface is bonded to the upper metal plate 20 via the solder layer 70 having a relatively uniform thickness.

As described above, the upper metal plate (emitter electrode) 20 is bonded to the plurality of pads 618 of the pellet 60 via the solder layer formed from the solder sheet 70A. The lower metal plate (collector electrode) 10 is also bonded to the flat lower surface of the pellet 60 via the solder layer formed by melting of the solder sheet 50A in a simultaneous process.

After the pellet 60 is bonded to the metal plates 10 and 20, the gate pad 619 is connected to the lead portion 30 via the wire 80 by wire bonding in the pellet 60 sandwiched between the metal plates 10 and 20.

After the wire bonding step, the pellet 60 sandwiched between the metal plates 10 and 20 is sealed by the sealing material 40.

Through the above steps, the semiconductor apparatus 1 according to the present embodiment is completed.

### (c) Summary

According to the present embodiment, the upper metal plate 20 is bonded to the upper surface of the pellet 60 on which the plurality of pads 618 is disposed by melting of solder (solder sheet).

In a method for manufacturing a general semiconductor apparatus, in a case where heat is supplied from the lower metal plate side to the pellet in a soldering step between the pellet and the metal plate, the temperature of the central portion of the pellet is likely to rise. In a case where the solder sheet is melted from the center portion side of the pellet, the solder in the portion where no melting occurs (for example, a portion on the outer peripheral side of the pellet) is pulled toward the center side of the pellet by the molten solder in the center portion of the pellet. In addition, due to the steps between the pads, the flow of the molten solder is hindered and/or the solder is aggregated (sink marks). As a result, there is a possibility that the solder melted from the central portion of the pellet as a base point does not wet and spread from the central portion of the pellet to the pad pattern of the outer peripheral portion of the pellet.

In addition, in a case where the solder sheet for forming the solder layer has deformation due to bending of the sheet or the like, there is a possibility that pressing of the solder sheet against the pellet becomes insufficient. In this case, solder sink marks may occur at the outer periphery of the pellet.

Therefore, in a general semiconductor apparatus, there is a possibility that a defect due to non-uniformity of the solder layer between the pellet and the upper metal plate occurs in the semiconductor apparatus.

In the semiconductor apparatus 1 according to the present embodiment, the upper metal plate 20 stacked above the upper surface of the pellet 60 has the protrusions 211 in the corner regions 219 of the surface S1 of the upper metal plate 20 facing the pellet 60. The protrusions 211 of the upper metal plate 20 overlap the pads 618 disposed on the outer periphery among the plurality of pads 618 of the pellet 60 in the direction perpendicular to the upper surface of the pellet 60. According to the present embodiment, the protrusions 211 of the upper metal plate 20 face the pattern of the pads 618 on the outer periphery of the pellet 60 at the corners of the upper metal plate 20 and the pad arrangement area PA.

The protrusions 211 form a space between the upper metal plate 20 and the pellet 60. The solder layer 70 is provided between the upper metal plate 20 and the pellet 60.

According to the present embodiment, the solder between the upper metal plate 20 and the pellet 60 melts with the protrusions 211 provided on the upper metal plate 20 as base points. With this configuration, the solder melts and flows from the outer peripheral portion toward the central portion of the area PA provided with the plurality of pads. The molten solder wets and spreads relatively uniformly on the undulating upper surface of the pellet 60 due to the steps 699 between the pads 618 and the insulating layer 629. Therefore, the semiconductor apparatus 1 according to the present embodiment can suppress the occurrence of cracks and sink marks in the solder layer 70 due to poor solder wetting.

As a result, in the semiconductor apparatus 1 according to the present embodiment, the solder layer 70 having a relatively uniform film thickness and film quality can be formed between the upper metal plate 20 and the pellet 60. Therefore, the semiconductor apparatus 1 according to the present embodiment can suppress a defect of the semiconductor apparatus due to the nonuniformity of the solder layer 70.

For example, according to the present embodiment, a solder sheet is used to form the solder layer 70. In the semiconductor apparatus 1 according to the present embodiment, even if the shape of the solder sheet is deformed, the solder sheet can be pressed against the pads 618 on the outer peripheral portion of the pellet 60 by the protrusions 211 provided on the upper metal plate 20. Therefore, the semiconductor apparatus 1 according to the present embodiment can suppress the turn-up and/or sink marks of the solder layer 70 on the pads 618 on the outer circumferential side in the area PA where the plurality of pads 618 are provided.

As a result, in the semiconductor apparatus 1 according to the present embodiment, it is possible to reduce the defect of the electrical connection between the upper metal plate 20 and the pellet 60 in the pads 618 (618A, 618B, and 618C) on the outer peripheral side of the area PA where the plurality of pads 618 is arranged.

The stress tends to concentrate on a portion where the film thickness of the solder layer is thin. Due to the concentration of the stress, defects in the solder layer and/or breakage of the pellet may occur.

According to the present embodiment, the relatively uniform formation of the solder layer 70 reduces the number of places where the thickness of the solder layer 70 is thin. As a result, in the semiconductor apparatus 1 according to the present embodiment, concentration of stress due to the thin film thickness of the solder layer 70 can be suppressed. As a result, the semiconductor apparatus 1 according to the present embodiment can reduce the damage of the pellet 60.

With the above-described effect, the semiconductor apparatus 1 according to the present embodiment can improve the manufacturing yield.

As described above, the semiconductor apparatus according to the present embodiment can suppress defects of the semiconductor apparatus 1.

### (d) Others

The semiconductor apparatus 1 according to the embodiment is not limited to a power device as long as it is a semiconductor apparatus having a structure in which a pellet (semiconductor chip) is sandwiched between two metal plates. For example, the semiconductor apparatus 1 according to the embodiment may be an analog circuit, a logic circuit, a processor, a communication circuit, or a memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor apparatus comprising:
a pellet including a first surface on which a plurality of pads are provided;
a first bonding material provided on the first surface; and
a first metal plate provided on the first bonding material, electrically connected to the plurality of pads, and including a second surface facing the first surface and a plurality of protrusions provided on the second surface, wherein
the plurality of protrusions respectively face one pad of the plurality of pads disposed at an end and another pad of the plurality of pads disposed at the other end in a direction in which the plurality of pads are aligned.

2. The semiconductor apparatus according to claim 1, wherein
each of the plurality of protrusions is disposed in a corner region of the first metal plate on the second surface.

3. The semiconductor apparatus according to claim 1, wherein
each of the plurality of protrusions has a first height.

4. The semiconductor apparatus according to claim 1, wherein
each of the plurality of pads extends in a first direction parallel to the first surface,
the plurality of pads are aligned, on an insulating layer covering the pellet, along a second direction intersecting the first direction and parallel to the first surface,
the plurality of pads include a first pad disposed at an end in the second direction and a second pad disposed at the other end in the second direction,
an end of the first pad in the first direction faces a first protrusion of the plurality of protrusions, and the other end of the first pad in the first direction faces a second protrusion of the plurality of protrusions, and
an end of the second pad in the first direction faces a third protrusion of the plurality of protrusions, and the other end of the second pad in the first direction faces a fourth protrusion of the plurality of protrusions.

5. The semiconductor apparatus according to claim 4, wherein
the plurality of pads include a third pad provided between the first pad and the second pad, and a fourth pad adjacent to the second pad in the first direction and adjacent to the third pad in the second direction, and
a portion of the third pad adjacent to the fourth pad faces a fifth protrusion of the plurality of protrusions.

6. The semiconductor apparatus according to claim 4, wherein
a distance between the first protrusion and the third protrusion in the second direction is equal to a distance between the first pad and the second pad in the second direction.

7. The semiconductor apparatus according to claim 6, wherein
a distance between the first protrusion and the second protrusion in the first direction is smaller than a dimension of the first pad in the first direction.

8. The semiconductor apparatus according to claim 1, wherein
the first bonding material is a solder sheet.

9. The semiconductor apparatus according to claim 1, further comprising:
a second metal plate provided on a third surface side of the pellet facing the first surface; and
a second bonding material between the pellet and the second metal plate, wherein
the first metal plate is an emitter electrode of an insulated gate bipolar transistor (IGBT), and
the second metal plate is a collector electrode of the IGBT.

10. The semiconductor apparatus according to claim 1, further comprising:
a second metal plate provided on a third surface side of the pellet facing the first surface; and
a second bonding material between the pellet and the second metal plate, wherein
the first metal plate is a source electrode of a metal-oxide-semiconductor field effect transistor (MOSFET), and
the second metal plate is a drain electrode of the MOSFET.
